(19) United States
(12) Patent Application Publication
(10) Pub. No.: US 2023/0048687 A1
(43) Pub. Date: Feb. 16, 2023

(54) QFN PACKAGING STRUCTURE AND QFN PACKAGING METHOD

(71) Applicant: JCET GROUP CO., LTD., Wuxi City (CN)

(72) Inventors: YUN GAO, Wuxi City (CN); TING LIU, Wuxi City (CN); YUESHENG ZHANG, Wuxi City (CN); HONGHAO SHI, Wuxi City (CN)

(21) Appl. No.: 17/887,390

(22) Filed: Aug. 12, 2022

(30) Foreign Application Priority Data
Aug. 13, 2021 (CN) 202110929807.3

(51) Int. Cl. H01L 23/552; H01L 23/495; H01L 23/31; H01L 21/56

(52) U.S. Cl. CPC H01L 23/552; H01L 23/49513; H01L 23/3107; H01L 23/49541; H01L 21/56; H01L 2224/29139; H01L 24/29

(57) ABSTRACT

The present invention provides a QFN packaging structure and QFN packaging method. The electromagnetic shielding layer as provided on the outer side of the QFN packaging structure by spacing at a certain interval from the leads may cooperate with the base island having the lug boss on the side edge, such that all surfaces of the chip can be electromagnetically shielded and protected while ensuring the insulation between the electromagnetic shielding layer and the leads.

### TECHNICAL FIELD

The present invention relates to the field of packaging technologies, in particular to a QFN packaging structure and QFN packaging method.

### BACKGROUND

With the development of electronic products in miniaturization and high density, packaging products tend to be miniaturized, and are developed at higher density, higher integration, and higher power. As an electronic component becomes smaller and operates at higher frequencies, a high-frequency chip may generate strong electromagnetic waves during the transportation and transmission, which may thereby cause interference or noise to other chips in the package or electronic components outside the package. Furthermore, due to excessively high integration of the electronic components, signal transmission lines between the electronic components are getting closer and closer, such that the electro-magnetic interference (EMI) between chips outside or inside an integrated circuit package may be increasingly severe.

For conventional quad flat no-leads (QFN) packaging structures, the leads are exposed to four side surfaces of a plastic package. However, an electromagnetic shielding layer generally directly covers over the plastic package, and is conductive. Thus, the direct contact between the conductive electromagnetic shielding layer and the leads may cause a short circuit between the leads, thereby affecting performances of the product.

### SUMMARY

An object of the present invention is to provide a QFN packaging structure and QFN packaging method.

The present invention provides a QFN packaging structure. The QFN packaging structure comprises a package frame, a chip and a plastic packaging layer. The package frame comprises at least one base island, and leads distributed on at least one side of the base island; the chip is provided on the base island and electrically connected to the leads; and the plastic packaging layer covers the package frame and the chip, and side surfaces and a bottom surface of the lead are exposed to the plastic packaging layer. The QFN packaging structure further comprises an electromagnetic shielding layer that covers at least side surfaces of the plastic packaging layer. The leads include a grounding lead, the electromagnetic shielding layer is spaced apart from the leads, and the electromagnetic shielding layer is electrically connected to the grounding lead via an electrical connector.

A lug boss that protrudes upwardly is provided on a side edge of the base island, and an upper surface of the lug boss is greater than a lower surface of the electromagnetic shielding layer.

As a further improvement of the present invention, an upper surface of the base island is higher than an upper surface of the lead, and an interval between the lead and the electromagnetic shielding layer ranges from 200 μm to 400 μm.

As a further improvement of the present invention, a conductive coating layer is provided between the grounding lead and the electromagnetic shielding layer, and the electromagnetic shielding layer and the grounding lead are electrically connected by the conductive coating layer.

As a further improvement of the present invention, the conductive coating layer is a conductive solder paste or a metal conductive layer.

As a further improvement of the present invention, the electromagnetic shielding layer is a metal film material such as copper, stainless steel, or titanium sputtering sandwich metal, or a conductive composite material such as a conductive resin having high-density metal filler of silver/copper, or a combination of at least two of the materials.

The present invention further provides a QFN packaging method, comprising:

providing a chip and a package frame that comprises a base island and leads distributed on at least one side of the base island, placing the chip on the base island, and electrically connecting the chip to the leads, wherein a lug boss that protrudes upwardly is provided on a side edge of the base island;

plastic-packaging the package frame and the chip to form a plastic packaging layer covering the package frame and the chip;

cutting part of the plastic packaging layer, and leaving at least part of the plastic packaging layer above the leads uncut to form a cutting slot;

forming an electromagnetic shielding layer on a surface of the plastic packaging layer;

cutting along a back surface of the package frame at a position of the cutting slot to acquire a single QFN packaging structure; and

providing an electrical connector between the electromagnetic shielding layer and the grounding lead.

As a further improvement of the present invention, cutting part of the plastic packaging layer specifically comprises:

cutting the plastic packaging layer at 200 to 400 μm above the leads.

As a further improvement of the present invention, the lug boss has a greater height than the plastic packaging layer as left above the leads.

As a further improvement of the present invention, providing the electrical connector specifically comprises:

coating a conductive solder paste or metallic conductive layer between the electromagnetic shielding layer and the grounding lead to form a conductive coating layer.

As a further improvement of the present invention, the electromagnetic shielding layer is a metal film material such as copper, stainless steel, or titanium sputtering sandwich metal, or a conductive composite material such as a conductive resin having high-density metal filler of silver/copper, or a combination of at least two of the materials.

The present invention can achieve the following beneficial effects. The electromagnetic shielding layer as provided on the outer side of the QFN packaging structure by spacing at a certain interval from the leads may cooperate with the base island having the lug boss on the side edge, such that all surfaces of the chip can be electromagnetically shielded and protected while ensuring the insulation between the electromagnetic shielding layer and the leads.

### BRIEF DESCRIPTION OF THE DRAWINGS

FIG. 1 is a schematic diagram of a QFN packaging structure according to an embodiment of the present invention;

FIG. 2 is a cross-sectional view of FIG. 1 at A-A;

FIG. 3 is a schematic flowchart of a QFN packaging method according to an embodiment of the present invention; and

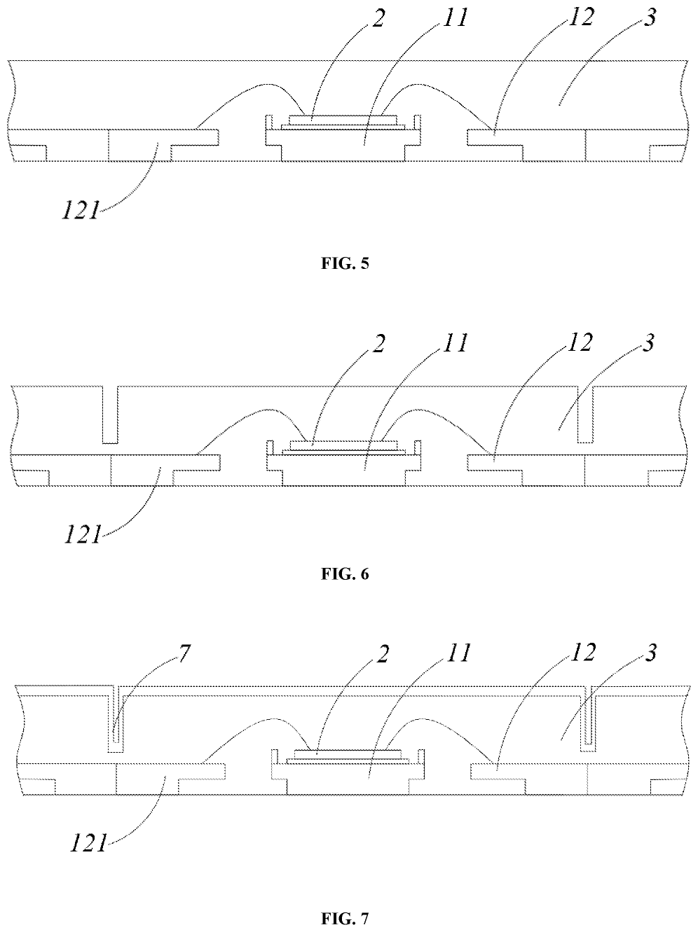

FIG. 4 to FIG. 9 are schematic flowcharts of steps of the QIN packaging method according to an embodiment of the present invention.

### DETAILED DESCRIPTION

In order to make the purpose, technical solutions, and advantages of the present application clearer, the technical solutions of the present application will be clearly and completely described below in conjunction with the specific embodiments of the present application and the corresponding drawings. Obviously, the described embodiments are only a part of the embodiments of the present application, rather than all of the embodiments. Based on the embodiments in present application, all other embodiments obtained by those of ordinary skill in the art without creative work shall fall within the protection scope of the present application.

The following describes the embodiments of the present invention in detail. Examples of the embodiments are shown in the accompanying drawings, in which the same or similar reference numerals indicate the same or similar elements or elements with the same or similar functions through the whole text. The following embodiments described with reference to the accompanying drawings are exemplary, and are only used to explain the present invention, but should not be understood as limiting the same.

For the convenience of description, this application uses terms representing the relative positions in space for description, such as “upper”, “lower”, “rear”, “front”, etc., which are used to describe the relationship of one unit or feature shown in the drawings relative to another unit or feature. The terms describing the relative positions in space may comprise different orientations of the equipment in use or operation other than the orientations shown in the drawings. For example, if a device in the drawings is turned over, the unit described as being “below” or “above” other units or features will be positioned “above” or “below” the other units or features. Therefore, the exemplary term “below” can encompass both spatial orientations of “below” and “above”.

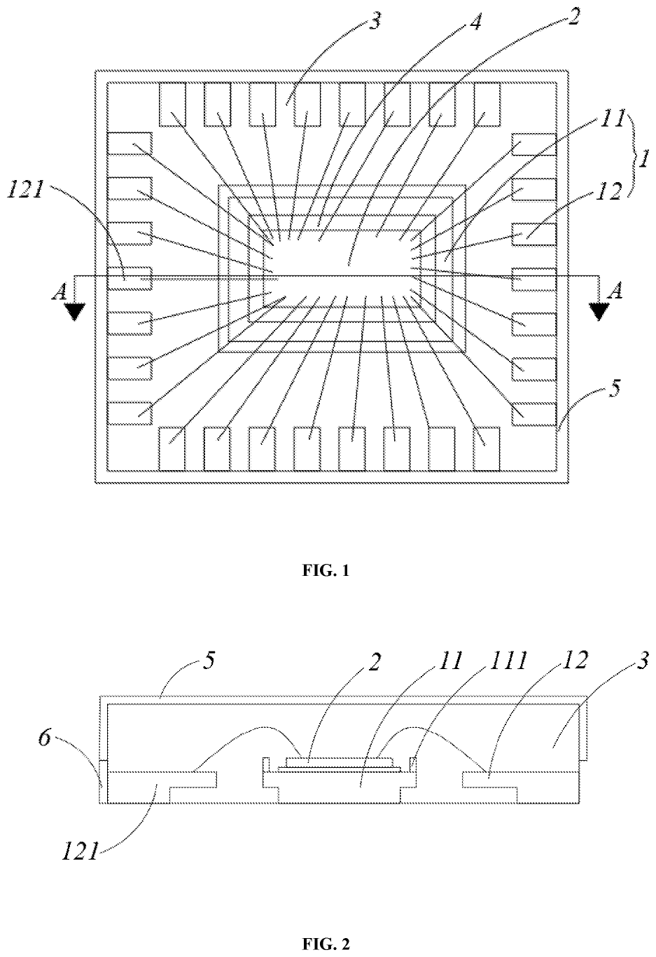

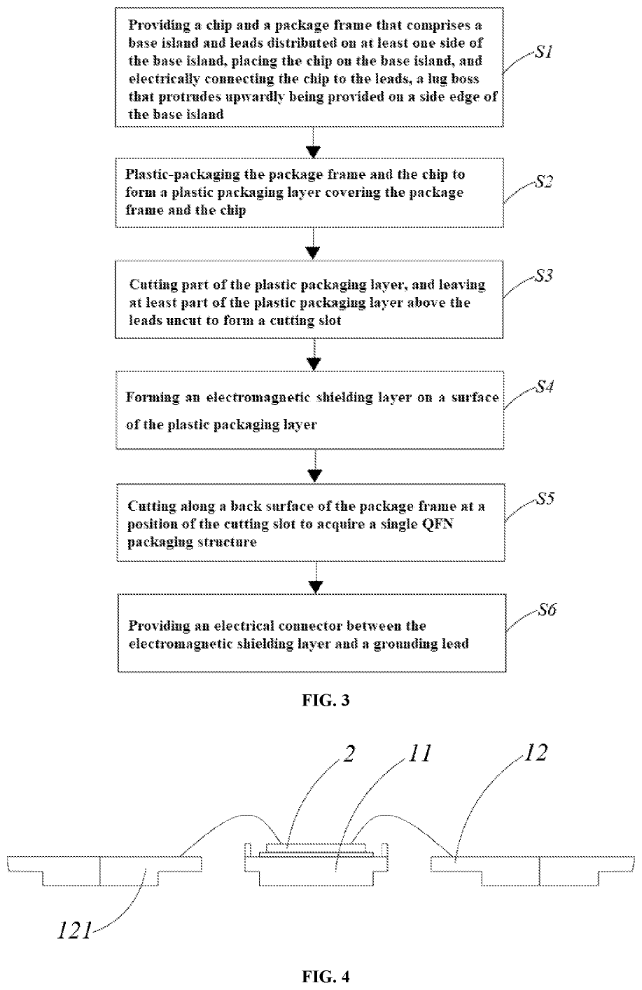

As shown in FIGS. 1 and 2, the present invention provides a QFN packaging structure, which comprises a package frame 1, a chip 2 and a plastic packaging layer 3. The package frame 1 comprises at least one base island 11, and leads 12 distributed on at least one side of the base island 11. The chip 2 is provided on the base island 11 and electrically connected to the leads 12. The plastic packaging layer 3 covers the package frame 1 and the chip 2, and side surfaces and a bottom surface of the lead 12 are exposed to the plastic packaging layer 3.

Exemplarily, in this embodiment, the package frame 1 comprises a base island 11 and leads 12 provided on the circumference of the four side edges. A back surface of the chip 2 is fixed on the base island 11 through a silver glue 4, and is electrically connected to the leads 12 by metal lead wires. In other embodiments, the package frame I may also be provided with a plurality of base islands 11, and the leads 12 may be provided on two sides of the base islands 11, which is not specifically limited in the present invention,

The leads 12 include a grounding lead 121 for connecting a grounding wire in an internal circuit of the chip 2 to a grounding wire in an external circuit. The grounding lead 121 may be defined as a low level or logic ground, and the grounding wire provides a low impedance path for backflow of an electric current and an equipotential reference point or plane for the circuit or system. Other leads 12 further comprise a function lead 12, an I/O lead 12 and a power lead 12.

A tin layer may be coated on the outer side of the lead 12 and the back surface of the base island 11, and functions to protect the packaging structure from being affected by an external environment.

The QFN packaging structure further comprises an electromagnetic shielding layer 5, which covers at least side surfaces of the plastic packaging layer 3. Specifically, the electromagnetic shielding layer 5 covers the side surfaces and a top surface of the plastic packaging layer 3. The leads 12 include a grounding lead 121, and the electromagnetic shielding layer 5 is spaced apart from the leads 12, such that the electromagnetic shielding layer 5 can be prevented from connecting with the leads and thereby from causing a short circuit to the leads 12, The leads 12 in the QFN package are usually disposed at the bottom of the packaging structure, and the side surface and the bottom surface as exposed to the plastic packaging layer 3 may form an electrical connection between the packaging structure and the external circuit. Thus, the electromagnetic shielding layer 5 covers all areas of the plastic packaging layer 3 excluding the part adjacent to the leads 12. The electromagnetic shielding layer 5 is electrically connected to the grounding lead 121 via an electrical connector, and is grounded via the grounding lead 121. The grounding may be designed as single-point grounding or multi-point grounding according to the needs of different circuits of the chip 2.

The electromagnetic shielding layer 5 may be a metal film material such as copper, stainless steel, or titanium sputtering sandwich metal, or a conductive composite material such as a conductive resin having high-density metal filler of silver/copper, or a combination of at least two of the materials, as long as the functions for reflecting and absorbing electromagnetic waves can be achieved.

A lug boss 111 that protrudes upwardly is provided on the side edge of the base island 11, and an upper surface of the lug boss 111 is greater than a lower surface of the electromagnetic shielding layer 5. Since the electromagnetic shielding layer 5 is spaced apart from the leads 12 at a certain interval, when a part of the chip 2 is disposed here, the electromagnetic shielding layer 5 may fail to fully cover the side surfaces of the chip 2. Therefore, the area that cannot be shielded by the electromagnetic shielding layer 5 may be filled by the boss lug 111 provided on the base island 11, such that all surfaces of the chip 2 can be electromagnetically shielded and protected by the electromagnetic shielding layer 5 and the base island 11. In addition, the boss lug 111 is able to prevent the silver glue from spilling out of the base island 11.

Preferably, the upper surface of the base island 11 in this embodiment is higher than the upper surface of the lead 12, and the interval between the lead 12 and the electromagnetic shielding layer 5 ranges from 200 μm to 400 μm, so as to ensure that no short circuit occurs between the electromagnetic shielding layer 5 and the lead 12 due to factors such as manufacturing errors. Preferably, the upper surface of the base island 11 is higher than the upper surface of the lead 12 by 200 μm, and the upper surface of the boss lug 111 is higher than the upper surface of the base island 11 by 200 μm.

Specifically, a conductive coating layer 6 is provided between the grounding lead 121 and the electromagnetic shielding layer 5 in this embodiment, and the electromagnetic shielding layer 5 and the grounding lead 121 are electrically connected via the conductive coating layer 6 which may be a conductive solder paste or a metal conductive layer. In addition, the electrical connection between the electromagnetic shielding layer 5 and the grounding lead 121 is simple and easy to implement by coating the conductive coating layer 6, and thereby is conducive to mass production. In other embodiments of the present invention, the electrical connection between the electromagnetic shielding layer 5 and the grounding lead 121 can also be achieved by providing a metal plating layer therebetween.

As shown in FIG, 3, the present invention further provides a QIN packaging method, which comprises the following steps S1-S6.

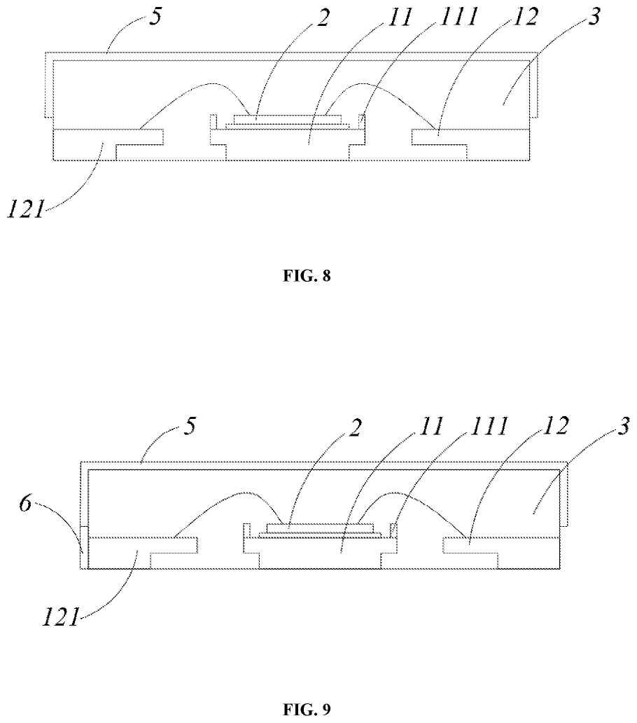

In S1, as shown in FIG. 4, a chip 2 and a package frame 1 are provided. The package frame 1 comprises a base island 11 and leads 12 distributed on at least one side of the base island 11, and a lug boss 111 that protrudes upwardly is provided on a side edge of the base island 11. Then, the chip 2 is placed on the base island 11, and is electrically connected to the leads 12.

Specifically, the chip 2 is pasted and fixed on the base island 11 through a silver glue 4, and is electrically connected to the leads 12 by metal lead wires.

In S2, as shown in FIG. 5, the package frame 1 and the chip 2 are plastically packaged to form a plastic packaging layer 3 for covering the package frame 1 and the chip 2.

Further, in some embodiments of the present invention, a tin layer may be plated on the lead 12 and the back surface of the base island 11.

In S3, as shown in FIG. 6, part of the plastic packaging layer 3 is cut, and at least part of the plastic packaging layer 3 above the leads 12 is left uncut to form a cutting slot 7.

Preferably, the plastic packaging layer 3 is cut at a position 200-400 μm above the leads 12. Moreover, the boss lug 111 has a greater height than the plastic packaging layer 3 as left above the leads 12.

In S4, as shown in FIG. 7, an electromagnetic shielding layer 5 is formed on the surface of the plastic packaging layer 3.

The electromagnetic shielding layer 5 is a metal film material such as copper, stainless steel, or titanium sputtering sandwich metal, or a conductive composite material such as a conductive resin having high-density metal filler of silver/copper, or a combination of at least two of the materials.

Specifically, the electromagnetic shielding layer 5 is formed on the surface of the plastic packaging layer 3 and in the cutting slot 7 by sputtering coating. In addition, a sum of the thicknesses of the two layers of the electromagnetic shielding layer 5 is smaller than a width of the cutting slot 7, thereby preventing depositing too many electromagnetic shielding layers 5 in the cutting slot 7.

Since the electromagnetic shielding layer 5 is spaced from the leads 12 by a certain interval, the electromagnetic shielding layer 5 as deposited on the surface of the plastic packaging layer 3 is insulated from the leads 12.

In S5, as shown in FIG. 8, the cutting is performed along the back surface of the package frame I at a position of the cutting slot 7 to acquire a single QFN packaging structure.

In S6, as shown in FIG. 9, an electrical connector is provided between the electromagnetic shielding layer 5 and the grounding lead 121.

Specifically, a conductive solder paste or metallic conductive layer is coated between the electromagnetic shielding layer 5 and the grounding lead 121 to form a conductive coating layer 6. In other embodiments, the electrical connection between the electromagnetic shielding layer 5 and the grounding lead 121 may also be achieved by plating a metal conductive layer, by providing a conductive connector, or the like.

In summary, the electromagnetic shielding layer as provided on the outer side of the QFN packaging structure by spacing at a certain interval from the leads may cooperate in the present invention with the base island having the lug boss on the side edge, such that all surfaces of the chip can be electromagnetically shielded and protected while ensuring the insulation between the electromagnetic shielding layer and the leads.

It should be understood that although the present invention is described in terms of embodiments in this description, not every embodiment comprises only one independent technical solution. The statement mode of the description is merely for clarity, and those skilled in the art should regard the description as a whole. The technical solutions in various embodiments may also be combined properly to develop other embodiments that can be understood by those skilled in the art.

The series of detailed illustrations listed above are merely for specifically illustrating the feasible embodiments of the present invention, but not intended to limit the protection scope of the present invention. Any equivalent embodiments or variations made without departing from the technical spirit of the present invention shall fall within the protection scope of the present invention.

What is claimed is:

1. A quad flat no-leads (QFN) packaging structure, comprising: a package frame, a chip and a plastic packaging layer, wherein the package frame comprises at least one base island, and leads distributed on at least one side of the base island; the chip is provided on the base island and electrically connected to the leads; and the plastic packaging layer covers the package frame and the chip, and side surfaces and a bottom surface of the lead are exposed to the plastic packaging layer; wherein
the QFN packaging structure further comprises an electromagnetic shielding layer that covers at least side surfaces of the plastic packaging layer; the leads include a grounding lead, and the electromagnetic shielding layer and the leads are provided at intervals; and the electromagnetic shielding layer is electrically connected to the grounding lead via an electrical connector; and
a lug boss that protrudes upwardly is provided on a side edge of the base island, and an upper surface of the lug boss is greater than a lower surface of the electromagnetic shielding layer.

2. The QFN packaging structure according to claim 1, wherein a conductive coating layer is provided between the grounding lead and the electromagnetic shielding layer, and the electromagnetic shielding layer and the grounding lead are electrically connected by the conductive coating layer.

3. The QFN packaging structure according to claim 2, wherein the conductive coating layer is a conductive solder paste or a metal conductive layer.

4. The QFN packaging structure according to claim 3, wherein the electromagnetic shielding layer is a metal film material such as copper, stainless steel, or titanium sputtering sandwich metal, or a conductive composite material such as a conductive resin having high-density metal filler of silver/copper, or a combination of at least two of the materials.

5. The QFN packaging structure according to claim 1, wherein an upper surface of the base island is higher than an upper surface of the lead, and an interval between the lead and the electromagnetic shielding layer ranges from 200 μm to 400 μm.

6. A quad flat no-leads (QFN) packaging method, comprising:
providing a chip and a package frame that comprises a base island and leads distributed on at least one side of the base island, placing the chip on the base island, and electrically connecting the chip to the leads, wherein a lug boss that protrudes upwardly is provided on a side edge of the base island;
plastic-packaging the package frame and the chip to form a plastic packaging layer covering the package frame and the chip;
cutting part of the plastic packaging layer, and leaving at least part of the plastic packaging layer above the leads uncut to form a cutting slot;
forming an electromagnetic shielding layer on a surface of the plastic packaging layer;
cutting along a back surface of the package frame at a position of the cutting slot to acquire a single QFN packaging structure; and
providing an electrical connector between the electromagnetic shielding layer and a grounding lead.

7. The QFN packaging method according to claim 6, wherein cutting part of the plastic packaging layer specifically comprises:
cutting the plastic packaging layer at 200 to 400 μm above the leads.

8. The QFN packaging method according to claim 6, wherein the lug boss has a greater height than the plastic packaging layer as left above the leads.

9. The QFN packaging method according to claim 6, wherein providing the electrical connector specifically comprises:
coating a conductive solder paste or metallic conductive layer between the electromagnetic shielding layer and the grounding lead to form a conductive coating layer.

10. The QFN packaging method according to claim 6, wherein the electromagnetic shielding layer is a metal film material such as copper, stainless steel, or titanium sputtering sandwich metal, or a conductive composite material such as a conductive resin having high-density metal filler of silver/copper, or a combination of at least two of the materials.
